(19) United States
(12) Patent Application Publication
(10) Pub. No.: US 2023/0283040 A1
(43) Pub. Date: Sep. 7, 2023

(54) METHOD FOR PRODUCING A RADIATION-EMITTING SEMICONDUCTOR BODY, AND RADIATION-EMITTING SEMICONDUCTOR BODY

(71) Applicant: OSRAM OPTO SEMICONDUCTORS GMBH, Regensburg (DE)

(72) Inventors: Jan Wagner, Regensburg (DE); Lars Naehle, Bad Abbach (DE); Sven Gerhard, Alteglofsheim (DE); Alfred Lell, Maxhütte-Haidhof (DE); Harald Koenig, Bernhardswald (DE); Christoph Eichler, Donaustauf (DE); Georg Brüderl, Burglengenfeld (DE); Martin Rudolf Behringer, Regensburg (DE)

(73) Assignee: ams-OSRAM International GmbH, Regensburg (DE)

(21) Appl. No.: 18/006,077

(22) PCT Filed: Jul. 20, 2021
(86) PCT No.: PCT/EP2021/070237

§ 371 Date: Jan. 19, 2023

(30) Foreign Application Priority Data
Jul. 21, 2020 (DE) 10 2020 119 227.4

(51) Int. Cl. H01S 5/02; H01S 5/40; H01S 5/22; H01S 5/026; H01L 33/00; H01L 33/32

(52) U.S. Cl. CPC H01S 5/0207; H01S 5/4087; H01S 5/22; H01S 5/4031; H01S 5/026; H01L 33/0075; H01L 33/32; H01S 5/34

(57) ABSTRACT

The invention relates to a method for producing a radiation-emitting semiconductor body, including the following steps: providing a growth substrate having a main surface; producing a plurality of distributor structures on the main surface of the growth substrate; epitaxially depositing a compound semiconductor material on the main surface of the growth substrate, wherein the epitaxial growth of the compound semiconductor material varies along the main surface because of the distributor structures, such that the epitaxial deposition produces an epitaxial semiconductor layer sequence having at least a first emitter region and a second emitter region on the main surface, the first emitter region and the second emitter region being laterally adjacent to each other in a top view of a main surface of the semiconductor body, and the first emitter region and the second emitter region producing electromagnetic radiation of different wavelength ranges during operation. The invention also relates to a radiation-emitting semiconductor body.

### CROSS-REFERENCE TO RELATED APPLICATIONS

This patent application is a national stage entry from International Application No. PCT/EP2021/070237, filed on Jul. 20, 2021, published as International Publication No. WO 2022/018071 A1 on Jan. 27, 2022, and claims priority to German Patent Application No. 10 2020 119 227.4, filed Jul. 21, 2020, the disclosures of all of which are incorporated by reference herein in their entireties.

### FIELD OF THE INVENTION

A method for producing a radiation-emitting semiconductor body, and a radiation-emitting semiconductor body, are specified.

### BACKGROUND OF THE INVENTION

Radiation-emitting semiconductor bodies are specified for example in the publication DE 10 2010 047 451 A1.

The aim is to specify an improved radiation-emitting semi-conductor body which is set up to generate electromagnetic radiation of different wavelength ranges. A further aim is to specify a simplified method for producing a radiation-emitting semiconductor body of this kind.

These objects are achieved by a method having the steps of claim 1 and by a radiation-emitting semiconductor body having the features of claim 10.

Advantageous embodiments and developments of the method and of the radiation-emitting semiconductor body are specified in the dependent claims.

### SUMMARY OF THE INVENTION

According to one embodiment of the method for producing a radiation-emitting semiconductor body, a growth substrate having a main face is first provided.

According to a further embodiment of the method, a multiplicity of distributor structures are generated on the main face of the growth substrate.

According to a further embodiment of the method, a compound semiconductor material is deposited epitaxially on the main face of the growth substrate, wherein the epitaxial growth of the compound semiconductor material varies along the main face because of the distributor structures, and so the epitaxial depositing produces an epitaxial semiconductor layer sequence having at least a first emitter region and a second emitter region on the main face. More preferably the distributor structures take the form of nongrowth areas, to which no homogeneously epitaxially deposited material is applied.

The compound semiconductor material comprises at least two different chemical elements. The compound semiconductor material is for example a III/V semiconductor material or a II/VI semiconductor material. A III/V compound semiconductor material in this case comprises at least one chemical element from the third group of the periodic table and at least one chemical element from the fifth group of the periodic table. A II/VI compound semiconductor material, conversely, comprises at least one chemical element from the second group of the periodic table and at least one chemical element from the sixth group of the periodic table.

The distributor structures are set up to vary the epitaxial growth of the semiconductor layer sequence along the main face. Properties of the epitaxial semiconductor layer sequence thus deposited are, in other words, different along the main face of the growth substrate. For example, a thickness or a chemical composition of the epitaxial semiconductor layer sequence varies along the main face. In general the epitaxial semi-conductor layer sequence is formed completely on regions of the main face that are free from the distributor structures. In other words, the main face is initially covered completely with the epitaxial semiconductor layer sequence, except for the regions in which the distributor structures are disposed.

According to a further embodiment of the method, the first emitter region and the second emitter region are disposed laterally next to one another in plan view onto a main face of the semiconductor body. More particularly the first emitter region and the second emitter region are not stacked atop one another in a stacking direction of the epitaxial semiconductor layer sequence.

According to a further embodiment of the method, the first emitter region and the second emitter region generate electro-magnetic radiation of different wavelength ranges. The first emitter region and the second emitter region preferably generate visible light. More preferably the first emitter region generates blue light and the second emitter region generates green light. It is, however, also possible for the emitter regions to generate visible light of other colors.

Furthermore, the method for producing a radiation-emitting semiconductor body is not limited to the generation only of two emitter regions. It is instead presently envisaged that more than two emitter regions are comprised by the epitaxial semi-conductor layer sequence to be deposited or form the epitaxial semiconductor layer sequence. More particularly all of the emitter regions which are comprised by the epitaxial semi-conductor layer sequence or which form it are disposed laterally next to one another in plan view onto the main face of the semiconductor body. The text below addresses only two emitter regions, for reasons of clarity. The corresponding features and embodiments may in each case also be embodied in the context of more than two emitter regions.

According to one embodiment, the method for producing a radiation-emitting semiconductor body comprises in particular the following steps:
providing a growth substrate having a main face,
generating a multiplicity of distributor structures on the main face of the growth substrate,
epitaxially depositing a compound semiconductor material on the main face of the growth substrate, wherein the epitaxial growth of the compound semiconductor material varies along the main face because of the distributor structures, and so the epitaxial depositing produces an epitaxial semiconductor layer sequence having at least a first emitter region and a second emitter region on the main face, wherein
the first emitter region and the second emitter region are disposed laterally next to one another in plan view onto a main face of the semiconductor body, and
the first emitter region and the second emitter region in operation generate electromagnetic radiation of different wavelength ranges.

More preferably the steps recited above are carried out in the specified order.

According to one embodiment of the method, the compound semi-conductor material is a III/V compound semiconductor material. More preferably the III/V compound semiconductor material is a nitride compound semiconductor material and conforms to the following formula: InₓAl_{y}Ga_{1-x-y}N with 0≤x≤1, 0≤y≤1 and x+y≤1.

According to a further embodiment of the method, the distributor structures are set up to vary the amount, available on the main face of the growth substrate, of a constituent of a precursor material of the compound semiconductor material to be deposited.

In general, for the epitaxial deposition of the semiconductor compound material, the growth substrate is provided in a closed-off volume. In the closed-off volume, in general, there is further provided a respective precursor material with a constituent for each or two or more of the chemical elements of the compound semiconductor material. For the deposition of a III/V compound semiconductor material, for example, at least one precursor material with a constituent for the group III chemical element subsequently present in the deposited epitaxial semiconductor layer sequence is provided. In the closed-off volume, the precursor material divides up in general into its constituents, and so the constituent of the precursor material for the group III element is available at the main face of the growth substrate.

Additionally provided is a precursor material with a constituent for the group V chemical element subsequently present in the deposited epitaxial semiconductor layer sequence. The distributor structures, then, are set up to vary the amount, available on or over the main face of the growth substrate, of a constituent of the precursor materials. For example, the distributor structures may increase or reduce the amount of one of the constituents of the precursor materials that is available on the main face of the growth substrate. Alternatively or additionally it is also possible for the distributor structures to establish a specific growth rate during epitaxial deposition of the epitaxial semiconductor layer sequence.

The epitaxial deposition more preferably comprises an organo-metallic vapor phase epitaxy (MOVPE for short).

As precursor materials for the group III chemical element indium, for example, one of the following materials is used: trimethylindium, dimethylaminopropyldimethylindium.

As precursor materials for the group III chemical element aluminum, for example, one of the following materials is used: trimethylaluminum (TMA), triethylaluminum (TEA).

As precursor materials for the group III chemical element gallium, for example, one of the following materials is used: trimethylgallium (TMG), triethylgallium (TEG).

As precursor materials for the group V chemical element nitrogen, for example, one of the following materials is used: phenylhydrazine, dimethylhydrazine, tert-butylamine, ammonia.

According to a further embodiment of the method, an amount, available during the epitaxial depositing, in the first emitter region, of a constituent of the precursor material of the compound semiconductor material to be deposited is different from the amount, in the second emitter region, of the constituent of the precursor material of the compound material to be deposited.

A distributor structure is formed, for example, by a recess in the main face of the growth substrate. The recess may be a trench or a hole. The trench or the hole has, for example, a round, a hexagonal, a rectangular or a triangular base area. Moreover, side faces of the trench and/or side faces of the hole may take the form of facets. Additionally, a distributor structure may also be formed by a porous region, which may be generated for example by etching in the main face of the growth substrate. Furthermore, a distributor structure may take the form of a ridge. The ridge for example comprises underetched sidewalls.

According to a further embodiment of the method, the distributor structure is formed by a coating which is applied on the main face of the growth substrate. The coating in this case is formed only in places on the main face of the growth substrate so as to form the distributor structure. The coating may for example comprise a dielectric or consist of a dielectric. Examples of suitable materials for the coating are the following: silicon nitride, silicon oxide.

A coating which comprises silicon nitride or silicon oxide or consists of one of these materials serves in general to increase the constituent of the precursor material for the group III element, by the coating influencing the growth of the epitaxial semiconductor layer through diffusion processes at the main face of the growth substrate or through alteration of the gas concentration over the growth substrate during the epitaxial deposition.

According to a further embodiment of the method, a distributor structure is formed by a region of the main face of the growth substrate that has a different tension from the rest of the main face. A change of this kind in the tension may be achieved, for example, through a different doping of the growth substrate in the region of the distributor structure.

According to a further embodiment of the method, the distributor structures are suitable for increasing the amount of the constituent of the precursor material for the compound semiconductor material over the main face of the growth substrate. Where the compound semiconductor material to be deposited is a III/V compound semiconductor material, the distributor structure increases, for example, the amount of the constituent of the precursor material for the group III element. For example, a coating which comprises silicon nitride or silicon oxide or consists of silicon nitride or silicon oxide is suitable for increasing the amount of a group III element over the main face of the growth substrate.

According to a further embodiment of the method, the distributor structures are suitable for reducing the amount of the constituent of the precursor material for the compound semiconductor material over the main face of the growth substrate. Where a III/V compound semiconductor material is to be deposited, then, for example, recesses, such as trenches, holes and/or porously etched regions, are suitable as distributor structures for reducing the amount of the constituent of the precursor material for the group III element over the main face of the growth substrate.

According to a further embodiment of the method, a distance between two directly adjacent emitter regions is not greater than 5 millimeters, preferably not greater than 1 millimeter and more preferably not greater than 100 micrometers.

The method described so far is suitable for generating a radiation-emitting semiconductor body, which is described in more detail below. All embodiments and features described in connection with the method may also be embodied in the case of the radiation-emitting semiconductor body, and vice versa.

According to one embodiment, the radiation-emitting semiconductor body comprises an epitaxial semiconductor layer sequence which comprises a compound semiconductor material. The epitaxial semiconductor layer sequence preferably comprises at least a first emitter region and a second emitter region. It is also possible, furthermore, for the epitaxial semiconductor layer sequence to be formed of the emitter regions. The first emitter region and the second emitter region are set up to generate, in operation, electromagnetic radiation of different wavelength ranges.

According to a further embodiment of the radiation-emitting semiconductor body, the first emitter region and the second emitter region are disposed laterally next to one another in plan view onto a main face of the semiconductor body.

According to a further embodiment of the radiation-emitting semiconductor body, a peak wavelength of an emission spectrum of the electromagnetic radiation which is emitted from the first emitter region is different by at least 2 nanometers, preferably by at least 5 nanometers, more preferably by at least 10 nanometers, more preferably by at least 50 nanometers, and very preferably by at least 100 nanometers from a peak wavelength of an emission spectrum of the electromagnetic radiation of the second emitter region.

According to a further embodiment of the radiation-emitting semiconductor body, the epitaxial semiconductor layer sequence is disposed on a main face of a growth substrate of the epitaxial semiconductor layer sequence, wherein the main face comprises a multiplicity of distributor structures.

The growth substrate comprises, for example, one of the following materials or is formed of one of the following materials: silicon carbide, sapphire, gallium nitride. These materials are especially suitable as growth substrate for a nitride compound semiconductor material.

According to a further embodiment of the radiation-emitting semiconductor body, the first emitter region and the second emitter region are disposed between two distributor structures or laterally on one side next to at least two distributor structures.

According to a further embodiment of the radiation-emitting semiconductor body, the distributor structures take the form of trenches in the main face of the growth substrate.

The trenches formed as distributor structures in the main face of the growth substrate have a width, for example, of more than 0.5 micrometer, preferably of at least 2 micrometers and more preferably of at least 4 micrometers. Moreover, the trenches formed as distributor structures in the main face of the growth substrate have a depth, for example, of at most 25 micrometers, preferably of at most 10 micrometers and more preferably at most 6 micrometers.

According to a further embodiment of the radiation-emitting semiconductor body, at least one distributor structure comprises at least two segments which are separate from one another and are embodied in the same way.

According to a further embodiment of the radiation-emitting semiconductor body, the first emitter region and the second emitter region comprise an active zone in which, in operation, electromagnetic radiation is generated. The active zone preferably comprises a first quantum film structure and at least one second quantum film structure, wherein the first quantum film structure within the first emitter region has a different thickness than within the second emitter region. Alternatively or additionally, the second quantum film structure within the first emitter region has a different thickness than within the second emitter region. In this way it is possible with advantage to generate two emitter regions, whose electromagnetic radiation exhibits emission spectra with peak wavelengths differing by at least 50 nanometers, preferably by at least 100 nanometers.

According to a further embodiment of the radiation-emitting semiconductor body, the first emitter region and the second emitter region are each comprised by a ridge waveguide. In other words, the two emitter regions are comprised by different ridge waveguides. In this way it is possible to generate a semiconductor body which emits electromagnetic laser radiation of different wavelength ranges from facets on side faces of the semiconductor body.

For the generation of electromagnetic laser radiation, the active zone takes the form of a laser medium, in which in operation a population inversion is generated in conjunction with a suitable resonator. Because of the population inversion, the electromagnetic radiation in the active region is generated by stimulated emission, leading to the formation of electro-magnetic laser radiation. Because of the generation of the electromagnetic laser radiation by stimulated emission, the electromagnetic laser radiation, in contrast to electromagnetic radiation generated by spontaneous emission, in general has a very high coherence length, a very narrow emission spectrum and/or a high degree of polarization.

According to a further embodiment of the radiation-emitting semiconductor body, a first contact point for electrically contacting the first emitter region is disposed on the first emitter region. Alternatively or additionally a second contact point for electrically contacting the second emitter region is disposed on the second emitter region. Hence electromagnetic radiation is generated in emitter regions within the epitaxial semiconductor layer sequence that are electrically separated from one another and are distanced from one another.

The radiation-emitting semiconductor body described here is suitable in particular to be used in a semiconductor laser chip. The semiconductor laser chip is, for example, an edge-emitting laser, which emits laser radiation from a laterally disposed facet. Additionally it may also be a surface-emitting laser, for instance a VCSEL (short for vertical cavity surface emitting laser), which emits laser radiation from a main face.

Alternatively it is also possible for the radiation-emitting semiconductor body to be part of a semiconductor light-emitting diode chip, which in particular emits electromagnetic radiation which has not been generated by population inversion.

With the method described here it is possible in a simple way to generate multiple emitter regions at wafer plane which emit electromagnetic radiation of different wavelengths. This offers the advantage that operating parameters of the emitter regions are influenced only a little. Moreover it is possible in particular to avoid a difficult production process by means of pick-and-place of individual semiconductor bodies emitting electromagnetic radiation of different emission spectra.

Further advantageous embodiments and developments of the radiation-emitting semiconductor body and of the method for producing it are evident from the exemplary embodiments described below in conjunction with the figures.

### BRIEF DESCRIPTION OF THE DRAWINGS

FIGS. 1 to 4 show stages of a method for producing a radiation-emitting semiconductor body according to one exemplary embodiment.

The method according to exemplary embodiments 1 to 4 is elucidated in more detail on the basis of FIGS. 5 to 7.

FIGS. 8 to 24 show schematic sectional representations of radiation-emitting semiconductor bodies according to various exemplary embodiments.

A radiation-emitting semiconductor body according to a further exemplary embodiment is elucidated in more detail on the basis of FIGS. 25 and 26.

A radiation-emitting semiconductor body according to a further exemplary embodiment is elucidated in more detail on the basis of FIGS. 27 and 28.

FIGS. 29 to 49 show schematic representations of radiation-emitting semiconductor bodies according to various exemplary embodiments.

### DETAILED DESCRIPTION

In the figures, elements which are identical, of the same kind or have the same effect are provided with the same reference symbols. The figures and the proportions of the elements represented in the figures to one another should not be considered to be to scale. Instead, individual elements, especially layer thicknesses, may be represented with exaggerated size for improved illustration and/or for improved understanding.

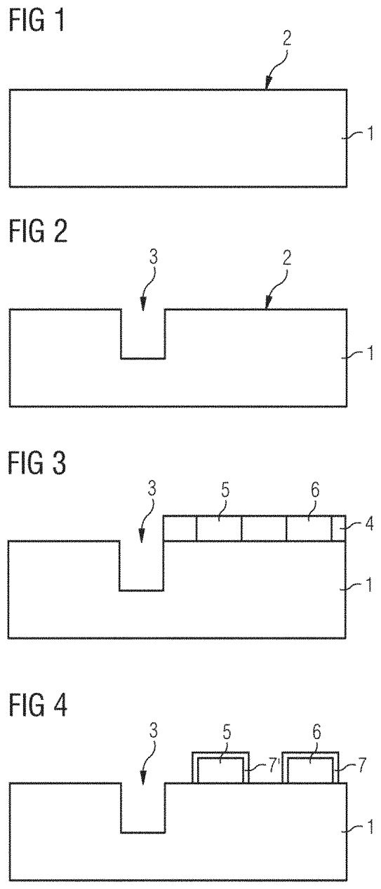

In the case of the method according to the exemplary embodiment of FIGS. 1 to 4, a growth substrate 1 having a main face 2 is provided first of all. The growth substrate 1 presently comprises sapphire, silicon carbide or gallium nitride (FIG. 1).

In a next step, a multiplicity of distributor structures 3 is generated on the main face 2 of the growth substrate 1, wherein presently, for reasons of clarity, only a single distributor structure 3 is represented in FIG. 2. In the present case a trench is generated as distributor structure 3 in the main face 2 of the growth substrate 1, by etching, for example. The trench has a rectangular cross-sectional area.

A nitride compound semiconductor material is then deposited epitaxially on the main face 2 of the growth substrate to form an epitaxial semiconductor layer sequence 4 (FIG. 3). For this purpose the growth substrate 1 is provided in a volume. Then a precursor material for the group III element of the nitride compound semiconductor material to be deposited is provided into the volume. For example, one of the following materials is a suitable precursor material for the group III element: trimethylindium, dimethylaminopropyldimethylindium, trimethylaluminum (TMA), triethylaluminum (TEA), trimethyl-galliuim (TMG), triethylgallium (TEG). The precursor material comprises a constituent for the group III element.

Additionally a precursor material with a constituent for the group V element of the III/V compound semiconductor material to be deposited is provided. For example, one of the following materials is suitable as a precursor material for the group III element: phenylhydrazine, dimethylhydrazine, tert-butylamine, ammonia.

The trench is presently set up to vary, more particularly to reduce, the amount of the constituent of the precursor material for the group III element that is available on the main face 2 of the growth substrate 1 during the epitaxial deposition.

Because of the variation in the constituent of the precursor material for the group III element along the main face 2 of the growth substrate 1, there is also variation in the epitaxial growth of the nitride compound semiconductor material along the main face 2. During the epitaxial deposition, because of the distributor structures 3, an epitaxial semiconductor layer sequence 4 is formed with at least a first emitter region 5 and a second emitter region 6 on the main face 2 of the growth substrate 1, these regions having different material compositions and/or thicknesses. Consequently the first emitter region 5 and the second emitter region 6 generate electro-magnetic radiation of different wavelength ranges. The first emitter region 5 and the second emitter region 6 are disposed laterally next to one another in plan view onto the semi-conductor body 1.

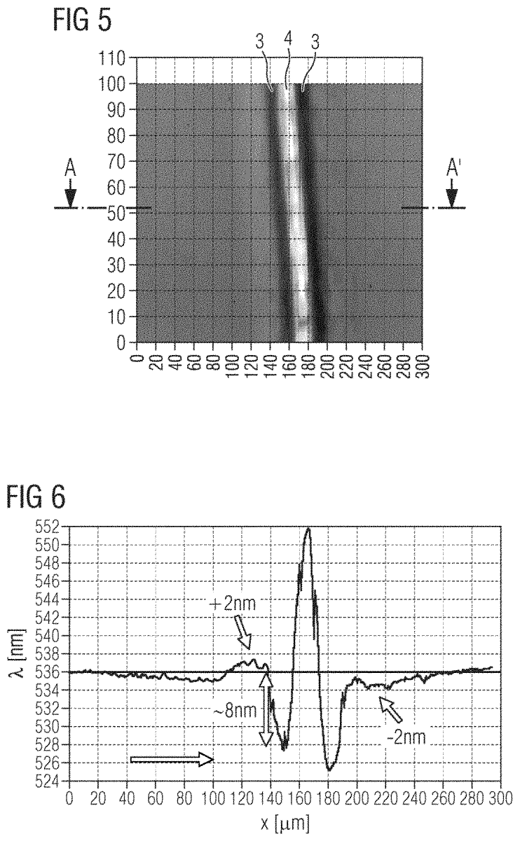

In a next step, the epitaxial semiconductor layer sequence 4 is structured, and so now only two mutually distanced emitter regions 5, 6 are disposed on the main face 2, while the rest of the main face 2 is free from the epitaxial semiconductor layer sequence 4 (FIG. 4). For example, the first emitter region 4 and the second emitter region 5 are each comprised by a ridge waveguide 7, 7′.

Additionally it would also be possible for only the emitter regions 5, 6 to be provided with an electrical contact, and so for only the emitter regions 5, 6, in operation of the radiation-emitting semiconductor body, to be supplied with power, so that electromagnetic radiation is generated only within the two emitter regions 5, 6.

FIG. 5 shows a spatially resolved photoluminescence measurement of an epitaxial semiconductor layer sequence 4 with an active zone 8. The epitaxial semiconductor layer sequence 4 is traversed by two trenches as distributor structure 3.

FIG. 6 shows measurement values for the peak wavelength λ of a photoluminescence along the line AA′ of FIG. 5. As shown by FIG. 6, the peak wavelength of the electromagnetic radiation generated by the active zone 8 of the epitaxial semiconductor layer sequence 4 changes by approximately +/−10 nanometers in the region of the distributor structures 3.

FIG. 7 shows the distribution of a peak wavelength λ of an emission spectrum of in each case three emitter regions 5, 6 between two distributor structures 3 which take the form of trenches. In this case the peak wavelength λ is plotted against the position x between the trenches.

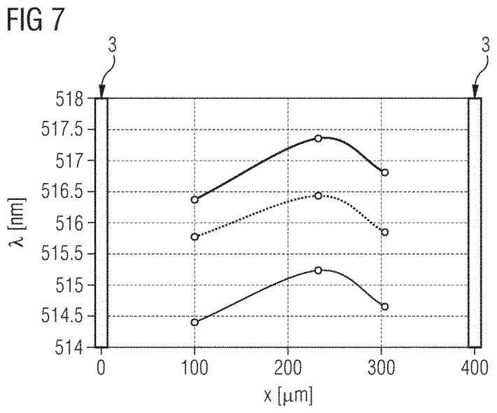

The radiation-emitting semiconductor body according to the exemplary embodiment of FIG. 8 comprises an epitaxial semi-conductor layer sequence 4 which is formed of a III/V semi-conductor material. The epitaxial semiconductor layer sequence 4 is formed of a first emitter region 5 and a second emitter region 6, the second emitter region 6 not being represented in the figure. The first emitter region 5 and the second emitter region 6 additionally comprise an active zone 8, in which electromagnetic radiation is generated in operation. In this case the first emitter region 5 emits electromagnetic radiation having an emission spectrum different from the emission spectrum of the electromagnetic radiation of the second emitter region 6. In other words, the first emitter region 5 and the second emitter region 6 generate electromagnetic radiation of different wavelength ranges. The first emitter region 5 and the second emitter region 6 are disposed laterally next to one another in plan view onto the main face of the semiconductor body.

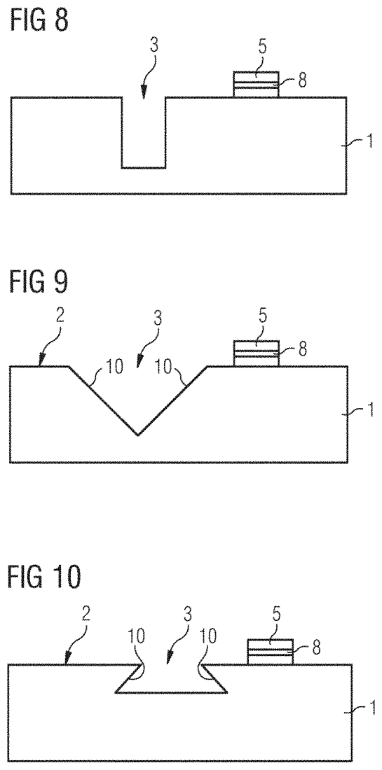

In contrast to the radiation-emitting semiconductor body according to the exemplary embodiment of FIG. 8, the distributor structure 3 of the radiation-emitting semiconductor body according to FIG. 9 comprises a trench with side faces in the form of facets. In other words, side faces 10 of the trench run diagonally to the main face 2 of the growth substrate 1. Through variations in the geometrical embodiment of the distributor structures 3, as for example by different depth, shape or faceting of the distributor structures 3, it is possible to obtain different emission spectra of the emitter regions 5, 6 deposited epitaxially on the growth substrate 1.

In contrast to the radiation-emitting semiconductor body according to FIG. 9, the distributor structure 3 of the radiation-emitting semiconductor body according to the exemplary embodiment of FIG. 10 comprises a trench with side faces 10 generated by underetching of the trench.

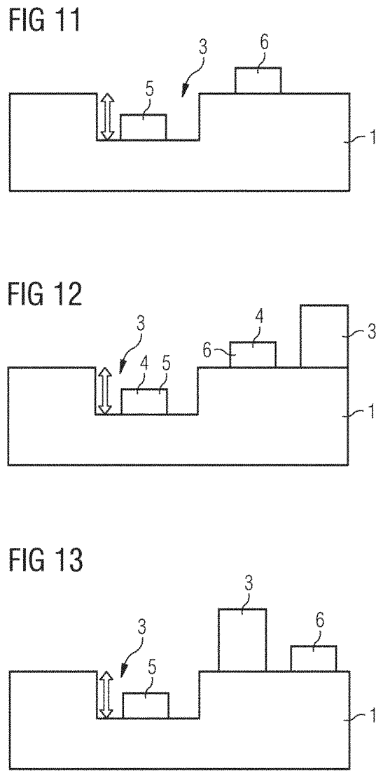

In contrast to the radiation-emitting semiconductor bodies according to the above-described exemplary embodiments, the radiation-emitting semiconductor body according to the exemplary embodiment of FIG. 11 comprises a first emitter region 5 which is disposed within a distributor structure 3 in the form of a trench.

In comparison to the radiation-emitting semiconductor body of FIG. 11, the radiation-emitting semiconductor body according to the exemplary embodiment of FIG. 12 comprises a further distributor structure 3, which is embodied as a coating. The coating is formed of silicon nitride or silicon oxide or comprises one of these materials. During the epitaxial growth of the epitaxial semiconductor layer sequence 4, this distributor structure 3 serves in particular to increase the amount of the constituent of precursor material for a group III element along the main face 2 of the growth substrate 1, while during the epitaxial growth the distributor structure 3 in trench form serves to reduce the amount of group III element on the main face 2 of the growth substrate 1. Through combination of the various distributor structures 3 it is possible to adjust the material composition within the emitter regions 5, 6 in a desired way.

The radiation-emitting semiconductor body according to the exemplary embodiment of FIG. 13 likewise comprises two different distributor structures 3, namely a trench and a coating, composed of silicon nitride or silicon oxide, for instance. In this case an emitter region 5 is disposed in the trench. The coating is disposed to the side of the further emitter region 6.

In contrast to the radiation-emitting semiconductor body according to the exemplary embodiment of FIG. 12, the coating in the case of the radiation-emitting semiconductor body according to the exemplary embodiment of FIG. 13 is disposed between the two emitter regions 5, 6.

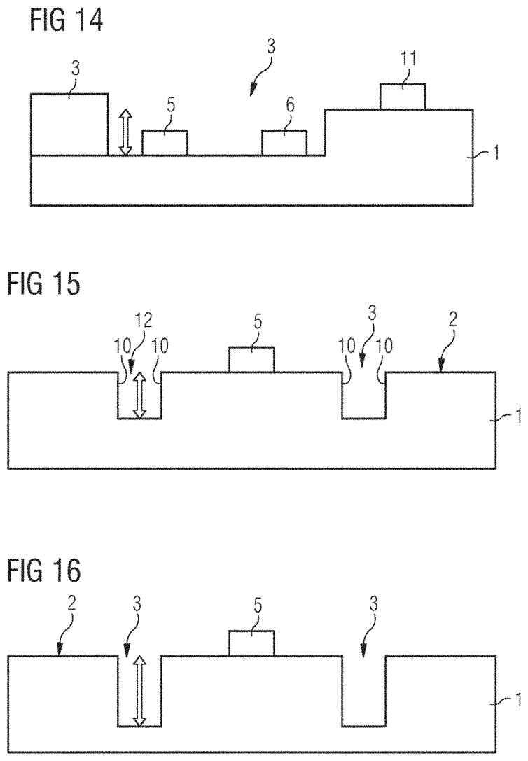

The radiation-emitting semiconductor body according to the exemplary embodiment of FIG. 14 comprises a distributor structure 3 in the form of a trench, in which two emitter regions 5, 6 are disposed. Additionally disposed in the trench is a further distributor structure 3, which is embodied as a coating. To the side of the trench, a further emitter region 11 has been applied to the growth substrate 1.

The radiation-emitting semiconductor body according to the exemplary embodiment of FIG. 15 has two trenches as distributor structures 3, between which an emitter region 5 is disposed. The trenches have side faces 10 which stand perpendicular to a main face 2 of a growth substrate 1.

The radiation-emitting semiconductor body according to the exemplary embodiment of FIG. 16 has two trenches as distributor structures 3, which have a greater depth than the trenches according to the exemplary embodiment of FIG. 15.

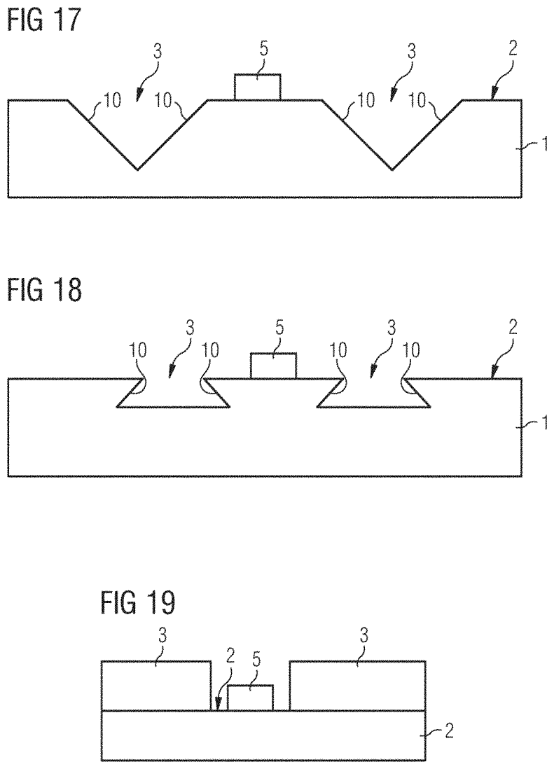

The radiation-emitting semiconductor body according to the exemplary embodiment of FIG. 17 has two trenches as distributor structures 3, between which an emitter region 5 is disposed. The trenches have side faces 10 which run diagonally to a main face 2 of a growth substrate 1. The trenches have a triangular cross-sectional area.

The radiation-emitting semiconductor body according to the exemplary embodiment of FIG. 18 has two trenches as distributor structures 3, between which an emitter region 5 is disposed. The trenches have side faces 10 which run diagonally to a main face 2 of a growth substrate 1. The trenches, in contrast to the trenches of the preceding exemplary embodiment, are underetched.

The radiation-emitting semiconductor body according to the exemplary embodiment of FIG. 19 has two coatings as distributor structures 3. Between the coatings an emitter region 5 is disposed.

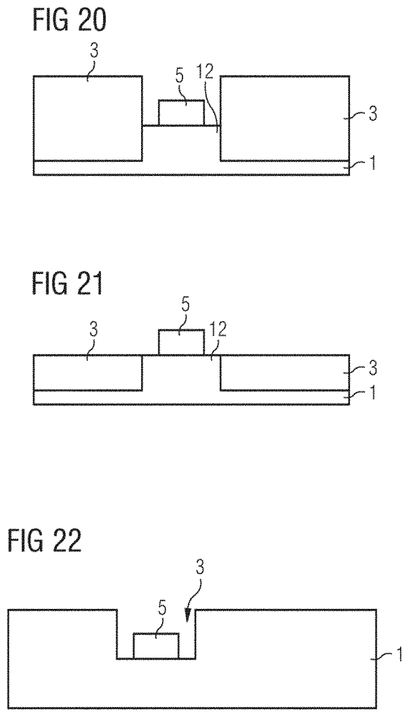

The radiation-emitting semiconductor body according to the exemplary embodiment of FIG. 20 has a projection 12 in a growth substrate 1, on which an emitter region 5 is disposed. Additionally, the radiation-emitting semiconductor body has two coatings as distributor structures 3, which are disposed laterally each bordering the projection 12 and which each project beyond the emitter region 5.

The radiation-emitting semiconductor body according to the exemplary embodiment of FIG. 21 has a projection 12 in a growth substrate 1, on which an emitter region 5 is disposed. Additionally, the radiation-emitting semiconductor body has two coatings as distributor structures 3, which are disposed laterally each bordering the projection 12 and which finish flush with the projection 12.

In the case of the radiation-emitting semiconductor body according to the exemplary embodiment of FIG. 22, a first emitter region 5 is disposed in a trench of a growth substrate 1 and serves as a distributor structure 3. The trench has a rectangular cross-sectional area.

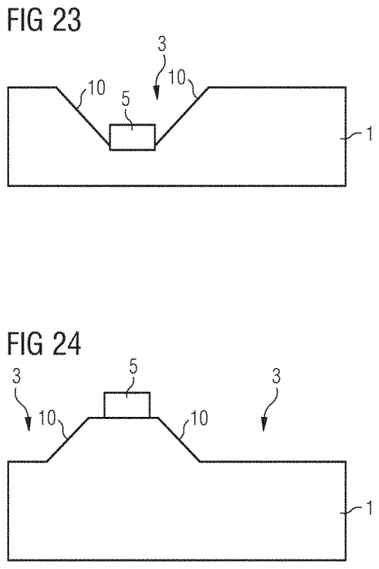

In the case of the radiation-emitting semiconductor body according to the exemplary embodiment of FIG. 23, in contrast to the radiation-emitting semiconductor body according to the exemplary embodiment of FIG. 22, an emitter region 5 is disposed in a trench which has faceted side faces 10. In the case of this exemplary embodiment, the side faces 10 run diagonally to a main face 2 of the growth substrate 1. The trench has a triangular cross-sectional area.

In the case of the radiation-emitting semiconductor body according to the exemplary embodiment of FIG. 24, an emitter region 5 is disposed between two trenches which have faceted side faces 10.

The radiation-emitting semiconductor body according to the exemplary embodiment of FIG. 25 has a distributor structure 3 which is disposed to the side of a first emitter region 5 and of a second emitter region 6. In the present case the first emitter region 5 and the second emitter region 6 are linear and run parallel to one another. In the present case the distributor structure 3 is embodied as a trench which is set up to lower a distribution of a constituent of a precursor material for a group III element on a main face 2 of a growth substrate 1. The trench and the two emitter regions 5, 6 run parallel to one another. Therefore the first emitter region 5, which is disposed nearer to the distributor structure 3 than the second emitter region 6, comprises a smaller amount of group III element.

FIG. 26 shows, schematically, a peak wavelength λ as a function of the position x of an emission spectrum of the electromagnetic radiation generated by the two emitter regions 5, 6 of the semiconductor body according to FIG. 25.

In contrast to the radiation-emitting semiconductor body according to FIG. 25, the radiation-emitting semiconductor body according to the exemplary embodiment of FIG. 27 has a distributor structure 3 which is embodied as a coating and is set up to increase a precursor material for a group III element on a main face 2 of a growth substrate 1. A second emitter region 6, which is further from the distributor structure 3 than a first emitter region 5, therefore comprises a lower amount of group III elements than the first emitter region 5.

FIG. 28 shows, schematically, a peak wavelength λ of an emission spectrum of the electromagnetic radiation generated by the two emitter regions 5, 6 of the semiconductor body according to FIG. 27, as a function of the position x.

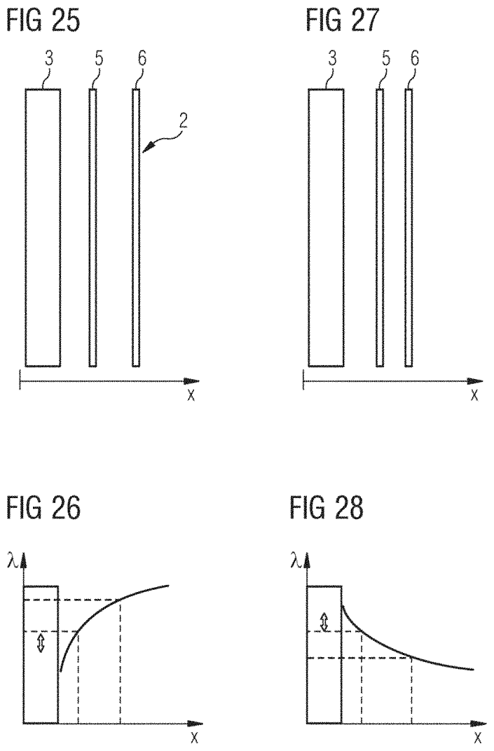

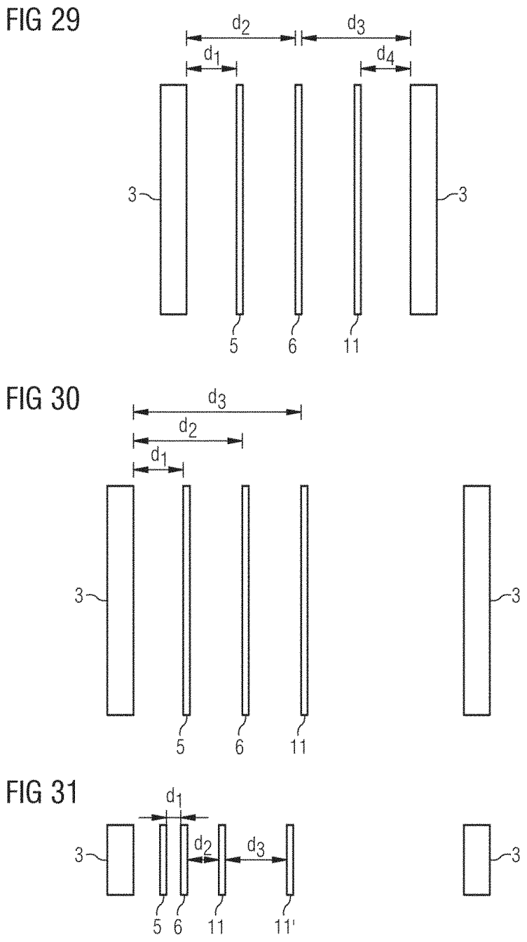

The radiation-emitting semiconductor body according to the exemplary embodiment of FIG. 29 has three emitter regions 5, 6, 11, disposed between two distributor structures 3. In this case the emitter regions 5, 6, 11 have distances equidistant from one another. A peak wavelength λ of the electromagnetic radiation emitted from the emitter regions 5, 6, 11 may be adjusted in a desired way through different distances d₁, d₂, d₃, d₄ from the distributor structures 3 on both sides of the emitter regions 5, 6, 11.

As represented schematically in FIG. 30, a peak wavelength λ may also be adjusted by different distances d₁, d₂, d₃ of the emitter regions 5, 6, 11 from the distributor structures 3 on one side. In other words, the emitter regions 5, 6, 11 need not be disposed symmetrically within the distributor structures 3, as represented in FIG. 29. Moreover, non-equidistant distances d₁, d₂, d₃ between the individual emitter regions 5, 6, 11, 11′ are also possible, in order, for example, to compensate a nonlinear dependence of the peak wavelength λ on the distance from the distributor structure 3 (see FIG. 31).

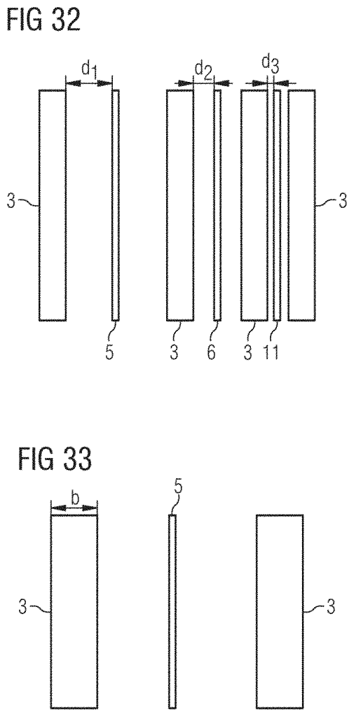

In the case of the radiation-emitting semiconductor body according to the exemplary embodiment of FIG. 32, four distributor structures 3 are disposed on the main face 2 of the growth substrate 1. Between pairs of distributor structures 3 there is an emitter region 5, 6, 11 positioned in each case. The distances d₁, d₂, d₃ between the distributor structures 3 are each different, so providing a different area for the growth of the respective emitter region 5, 6, 11. Thus different growth rates of the epitaxial semiconductor layer sequence 4 and/or amounts of the constituents of the precursor material for the group III element may be obtained during epitaxial deposition, thus forming quantum film structures 9 of different thickness and/or material composition within the emitter regions 5, 6, 11.

As FIGS. 33 and 34 illustrate, widths b and/or depths of the distributor structures 3 may differ, in order to realize different emission spectra of the electromagnetic radiation generated by the emitter regions 5, 6, 11.

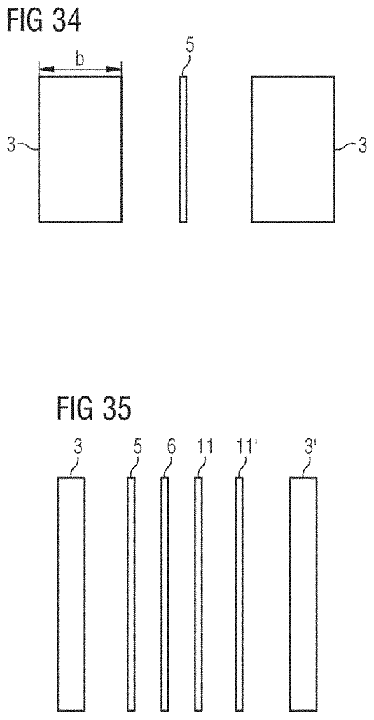

The radiation-emitting semiconductor body according to the exemplary embodiment of FIG. 35 comprises two distributor structures 3, between which four emitter regions 5, 6, 11, 11′ are disposed. One distributor structure 3 in this case is set up to increase a constituent of a precursor material for a group III element over a main face 2 of a growth substrate 1 during epitaxial deposition. The other distributor structure 3, conversely, is set up to reduce the constituent of the precursor material for a group III element along the main face 2 of the growth substrate 1. In this way as well, emitter regions 5, 6, 11, 11′ can be generated that emit electro-magnetic radiation of different wavelength ranges in operation.

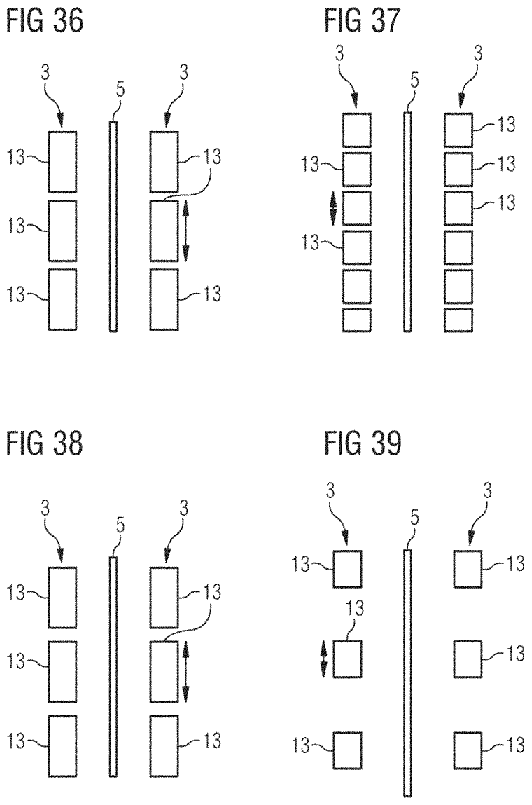

The radiation-emitting semiconductor body according to the exemplary embodiment of FIG. 36 has distributor structures 3 with different segments 13 separate from one another. The segments 13 are embodied in the same way. An emitter region 5 is disposed between two distributor structures 3.

The distributor structures 3 in the case of the radiation-emitting semiconductor body according to the exemplary embodiment of FIG. 37 also comprise distributor structures 3 having segments 13. In this case an area fraction of the segments 13 of the distributor structures 3 is equal to an area fraction of the segments 13 of the distributor structures 3 of the exemplary embodiment of FIG. 36.

It is also possible, furthermore, for the area fractions of the segments 13 of the distributor structures 3 to vary (see FIGS. 38 and 39).

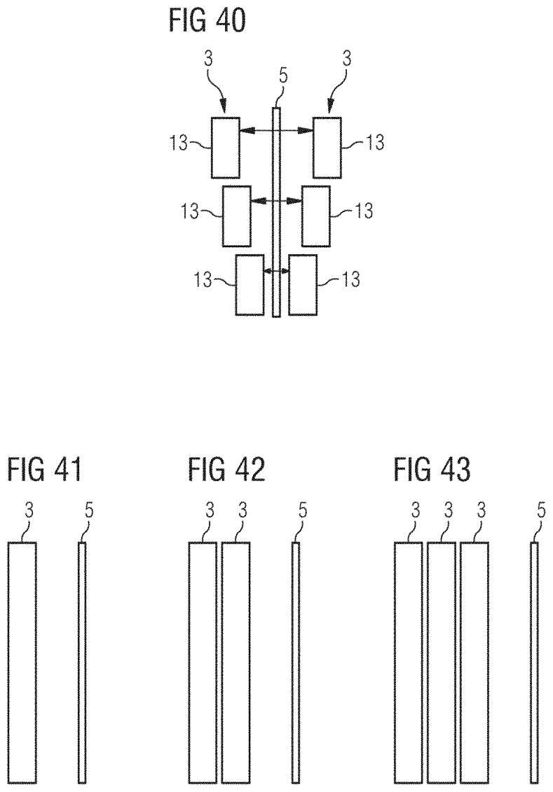

The radiation-emitting semiconductor body according to the exemplary embodiment of FIG. 40 likewise comprises distributor structures 3 having different segments 13 separated from one another. The segments 13 of a common distributor structure 3 in this case have different distances d₁, d₂, dfrom an emitter region 5 which is disposed between the two distributor structures 3.

As shown in FIGS. 41, 42 and 43, it is also possible to dispose multiple distributor structures 3 next to an emitter region 5. In the case of the radiation-emitting semiconductor body according to the exemplary embodiment of FIG. 41, a single distributor structure 3 is disposed next to the emitter region 5; in the case of the radiation-emitting semiconductor body according to the exemplary embodiment of FIG. 42, exactly two distributor structures 3 are disposed next to the emitter region 5; and in the case of the radiation-emitting semiconductor body according to the exemplary embodiment of FIG. 43, exactly three distributor structures 3 are disposed next to the emitter region 5. An arrangement of this kind of multiple distributor structures 3 next to an emitter region 5 in general has the advantage of a lower tension, relative to a single, wider distributor structure 3.

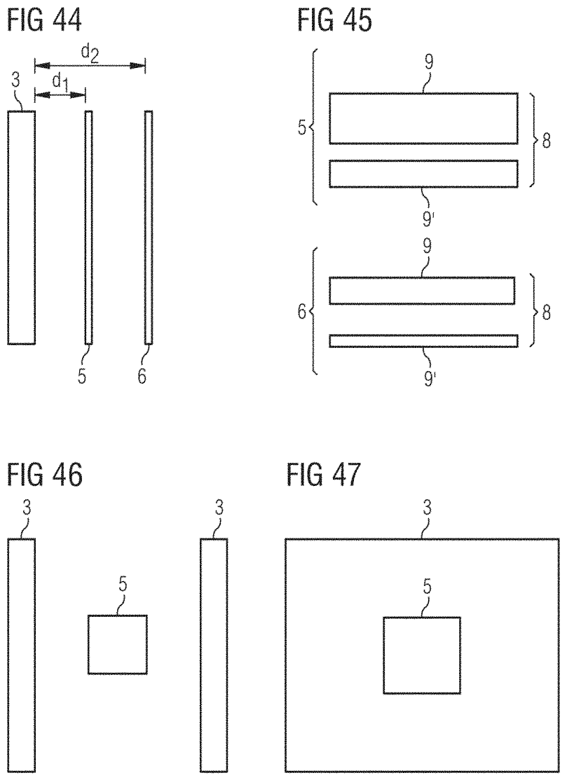

The radiation-emitting semiconductor body according to the exemplary embodiment of FIGS. 44 and 45 comprises a distributor structure 3 and two emitter regions 5, 6. The two emitter regions 5, 6 are linear and run parallel to one another and also parallel to the distributor structure 3, which is disposed to the side of the two emitter regions 5, 6. Depending on the distance d₁, d₂ of the two emitter regions 5, 6 from the distributor structure 3, there are differences in the epitaxial growth rates and/or in the amount of a group III element within the compound semiconductor material of the emitter regions 5, 6. With preference the indium content of the two emitter regions 5, 6 varies one from the other (FIG. 44).

The first emitter region 5 and the second emitter region 6 in the present case have an active zone 8 in which the electro-magnetic radiation is generated in operation. The active zone 8 additionally comprises a first quantum film structure 9 and a second quantum film structure 9′ (FIG. 45). In this case the first quantum film structure 9 preferably has a different thickness within the first emitter region 5 than within the second emitter region 6. The second quantum film structure 9′ likewise has a different thickness within the first emitter region 5 than within the second emitter region 6. The first emitter region 5 generates electromagnetic radiation only in the second quantum film structure 9′, since the first quantum film structure 9 has too great a thickness. Moreover, the second emitter region 6 generates electromagnetic radiation only in the first quantum film structure 9, since the second quantum film structure 9′ is too thin.

In conjunction with FIGS. 25 to 45, radiation-emitting semiconductor bodies have been described which have linear emitter regions 5, 6, 11, 11′. These regions are suitable in particular to be encompassed each by a ridge waveguide 7, 7′, so that the radiation-emitting semiconductor body emits electromagnetic laser radiation of the emitter regions 5, 6, 11, 11′ from a side face. Described below are exemplary embodiments wherein the radiation-emitting semiconductor body emits electromagnetic radiation, generated in the emitter regions 5, 6, 11, 11′, from a main face (referred to as “surface emitters”).

The radiation-emitting semiconductor body according to the exemplary embodiment of FIG. 46 has two linear distributor structures 3 which are disposed to the side of an emitter region 5. The emitter region 5 in this case is rectangular.

The radiation-emitting semiconductor body according to the exemplary embodiment of FIG. 47 likewise comprises an emitter region 5 having a rectangular base form. The distributor structure 3 in this case has a frame shape and is disposed likewise with a rectangular base structure around the emitter region 5. The distributor structure 3 borders the emitter region 5 directly.

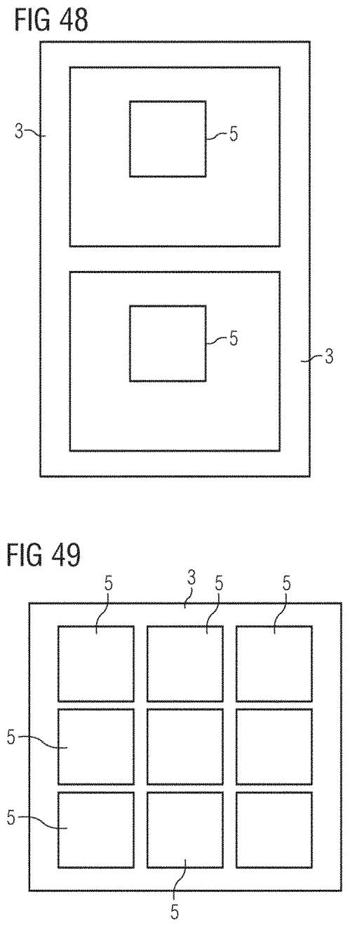

The radiation-emitting semiconductor body according to the exemplary embodiment of FIG. 48 comprises two rectangular emitter regions 5, 6, each surrounded in frame fashion by a distributor structure 3. The distributor structure 3 in this case is at a distance from the emitter structure 5.

The radiation-emitting semiconductor body according to the exemplary embodiment of FIG. 49 comprises a multiplicity of emitter regions 5, which are arranged along rows and columns. A distributor structure 3 is formed in frame fashion around the emitter regions 5 and fills in spaces between the emitter regions 5.

Presently, in the figures, in some cases only a single emitter region 5 is shown. This serves merely for greater clarity. All of the semiconductor bodies have at least two emitter regions 5, 6. The semiconductor body also has a multiplicity of distributor structures 3, even if, only for reasons of clarity, a single distributor structure 3 is shown and described.

The invention is not confined to the exemplary embodiments because of the description on the basis of those embodiments. The invention instead encompasses every new feature and also every combination of features, including in particular every combination of features in the claims, even if that feature or that combination is not itself specified explicitly in the claims or exemplary embodiments.

1. A method for producing a radiation-emitting semiconductor body:
providing a growth substrate having a main face,
generating a multiplicity of distributor structures on the main face of the growth substrate,
epitaxially depositing a compound semiconductor material on the main face of the growth substrate, wherein the epitaxial growth of the compound semiconductor material varies along the main face because of the distributor structures, and so the epitaxial depositing produces an epitaxial semiconductor layer sequence having at least a first emitter region and a second emitter region on the main face, wherein
the first emitter region and the second emitter region are disposed laterally next to one another in plan view onto a main face of the semiconductor body, and
the first emitter region and the second emitter region in operation generate electromagnetic radiation of different wavelength ranges.

2. The method as claimed in claim 1, in which the compound semiconductor material is a III/V compound semiconductor material.

3. The method as claimed in claim 1, in which the III/V semiconductor material is a nitride compound semiconductor material and conforms to the following formula:
InₓAl_{y}Ga_{1-x-y}N with 0£x£1, 0£y£1 and x+y£1.

4. The method as claimed in claim 1, in which the distributor structures are set up to vary the amount, available on the main face of the growth substrate, of a constituent of a precursor material of the compound semiconductor material to be deposited.

5. The method as claimed in claim 4, in which a distributor structure is formed by a coating on the main face of the growth substrate.

6. The method as claimed in claim 1, in which an amount, available during the epitaxial depositing, in the first emitter range, of a constituent of a precursor material of the compound semiconductor material to be deposited is different from the amount, in the second emitter region, of the constituent of the precursor material of the compound semiconductor material to be deposited.

7. The method as claimed in claim 1, in which the distributor structures are suitable for increasing the amount of a constituent of a precursor material for the compound semiconductor material over the main face of the growth substrate.

8. The method as claimed in claim 1, in which the distributor structures are suitable for reducing the amount of a constituent of a precursor material for the compound semiconductor material over the main face of the growth substrate.

9. The method as claimed in claim 1, in which a distance between two directly adjacent emitter regions is not greater than 5 millimeters.

10. A radiation-emitting semiconductor body having:
an epitaxial semiconductor layer sequence which comprises a compound semiconductor material, wherein
the epitaxial semiconductor layer sequence comprises at least a first emitter region and a second emitter region or is formed of at least a first emitter region and a second emitter region, wherein
the first emitter region and the second emitter region in operation generate electromagnetic radiation of different wavelength ranges, and
the first emitter region and the second emitter region are disposed laterally next to one another in plan view onto a main face of the semiconductor body.

11. The radiation-emitting semiconductor body as claimed in claim 10, in which
a peak wavelength of an emission spectrum of the electromagnetic radiation emitted from the first emitter region is different by at least 2 nanometers from a peak wavelength of an emission spectrum of the electromagnetic radiation of the second emitter region.

12. The radiation-emitting semiconductor body as claimed in claim 10, in which
the epitaxial semiconductor layer sequence is disposed on a main face of a growth substrate of the epitaxial semiconductor layer sequence,
wherein the main face of the growth substrate comprises a multiplicity of distributor structures, wherein the distributor structures comprise a coating of the main face of the growth substrate.

13. The radiation-emitting semiconductor body as claimed in claim 1, in which
the first emitter region and the second emitter region are disposed between two distributor structures or laterally on one side next to at least two distributor structures.

14. The radiation-emitting semiconductor body as claimed in claim 12, in which
the distributor structures are embodied as trenches in the main face of the growth substrate.

15. The radiation-emitting semiconductor body as claimed in claim 12, in which
at least one distributor structure comprises at least two segments which are separate from one another and are of the same kind.

16. The radiation-emitting semiconductor body as claimed in claim 10, in which
the first emitter region and/or the second emitter region comprise an active zone in which in operation the electromagnetic radiation is generated, and
the active zone comprises a first quantum film structure and at least one second quantum film structure, wherein
the first quantum film structure within the first emitter region has a different thickness than within the second emitter region, and/or
the second quantum film structure within the first emitter region has a different thickness than within the second emitter region.

17. The radiation-emitting semiconductor body as claimed in claim 10, in which
the first emitter region and the second emitter region are each comprised by a ridge waveguide.

18. The radiation-emitting semiconductor body as claimed in claim 10, in which
on the first emitter region a first contact point for electrically contacting the first emitter region is disposed, and/or
on the second emitter region a second contact point for electrically contacting the second emitter region is disposed.

19. A semiconductor laser chip having a radiation-emitting semiconductor body as claimed in claim 10.

20. A semiconductor light-emitting diode chip having a radiation-emitting semiconductor body as claimed in claims 10.
